(19) United States
(12) Patent Application Publication
(10) Pub. No.: US 2014/0311775 A1
(43) Pub. Date: Oct. 23, 2014

(54) CIRCUIT BOARD STRUCTURE

(71) Applicants: HON HAI PRECISION INDUSTRY CO., LTD., New Taipei (TW); HONG FU JIN PRECISION INDUSTRY (ShenZhen) CO., LTD, Shenzhen (CN)

(72) Inventor: CHAO-RONG LAI, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 14/144,522

(22) Filed: Dec. 30, 2013

(30) Foreign Application Priority Data
Apr. 23, 2013 (CN) 2013101418265

(51) Int. Cl. H05K 1/11

(52) U.S. Cl. CPC H05K 1/115
USPC 174/255

(57) ABSTRACT

A circuit board structure includes a circuit board and at least one adsorption strip set on the circuit board. The circuit board defines at least one group of pin holes arranged along a predetermined line to receive a number of pins of an electronic component. The adsorption strip absorbs excess conducting material between adjacent pins during a wave-soldering process.

### 1. TECHNICAL FIELD

The disclosure generally relates to electronic equipment, and particularly to a circuit board structure.

### 2. DESCRIPTION OF RELATED ART

Generally, pins of an electronic component are coated with tin using a wave-soldering process when a circuit board is made. However, the conducting material on the pins is easy to adhere together if two adjacent pins are too close, which leads to a low yield of the circuit board.

Therefore, it is desirable to provide a means to overcome the above-mentioned problems.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustraconducting materialg the principles of the disclosure. Moreover, in the drawings, like reference numerals designate corresponding parts throughout the views.

FIG. 1 is a schematic view of an embodiment of a circuit board structure.

### DETAILED DESCRIPTION

The disclosure is illustrated by way of example and not by way of limitation in the FIGURE of the accompanying drawings in which like references indicate similar elements. It should be noted that references to “an” or “one” embodiment in this disclosure are not necessarily to the same embodiment, and such references can mean “at least one.”

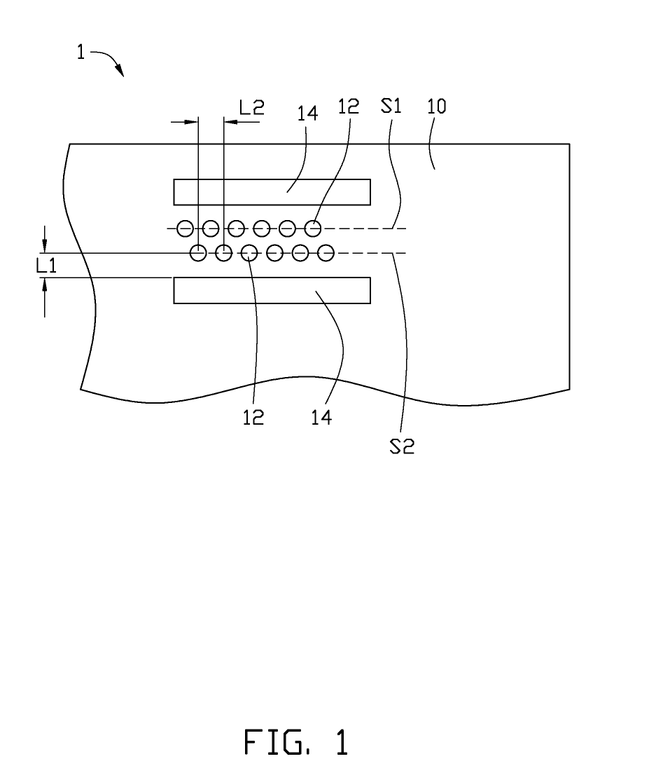

FIG. 1 shows one embodiment of a circuit board structure 1 that includes a circuit board 10 and at least one adsorption strip 14 set on the circuit board 10. The circuit board 10 defines at least one group of pin holes 12 arranged along a predetermined line 51 or a predetermined line S2. In the illustrated embodiment, the circuit board 10 defines two groups of pin holes 12 and includes two adsorption strips 14. A first group of pin holes 12 is arranged along the predetermined line S1, and a second group of pin holes 12 is arranged along the predetermined line S2. The predetermined lines S1 and S2 pass through centers of the first and second groups of pin holes 12, respectively. The adsorption strips 14 are isolated from circuits of the circuit board 10. The adsorption strips 14 are located adjacent to a corresponding group of pin holes 12, and extend along a direction substantially parallel to the predetermined lines S1 and S2. A first distance L1 between a side of the adsorption strip 14 adjacent to the corresponding group of pin holes 12 and the predetermined line S1 or S2 is less than a second distance L2 between two centers of adjacent pin holes 12. In the illustrated embodiment, the circuit board 10 is a printed circuit board, and the predetermined lines S1 and S2 are substantially straight. In other embodiments, one or both of the predetermined lines S1 and S2 can be a curved line, and the circuit board 10 can define more groups of pin holes 12.

The pin holes 12 are used to receive a number of pins (not shown) of an electronic component (not shown). A wave-soldering process coats a conducting material onto the pins after the pins are received in the pin holes 12, to fasten and electrically connect the pins to the circuit board 10. The pin holes 12 are spacially defined according to the pins of the electronic component. In one embodiment, each group of pin holes 12 corresponds to one group of pins, and the conducting material is tin.

The adsorption strip 14 absorbs excess conducting material during the wave-soldering process to prevent adjacent pins from short-circuiting due to build-up of the conducting material between the two adjacent pins. In one embodiment, the adsorption strip 14 is a substantially rectangular copper strip. Because the adsorption strip 14 is bigger than a single pin of the electronic component, a surface area of the adsorption strip 14 is greater than a surface area of the pins. Thus, a surface tension of the excess conducting material on the adsorption strip 14 is greater than a surface tension of the conducting material between two adjacent pins, so the excess conducting material between two adjacent pins is attracted to the adsorption strip 14.

Each adsorption strip 14 absorbs the excess conducting material between adjacent pins received in the pin holes 12 arranged along the corresponding predetermined line S1 or S2. Numbers of the adsorption strips 14 can be changed according to numbers of the groups of pins and groups of pin holes 12. Thus, if there are different groups of the pin holes 12 correspondingly arranged along the predetermined lines S1 and S2 in different directions, the corresponding adsorption strip 14s are set to absorb the redundant conducting material. In the illustrated embodiment, there are two adsorption strips 14 correspondingly set at two opposite outer sides of two groups of the pin holes 12 arranged along two parallel predetermined lines S1 and S2.

It is believed that the present embodiments and their advantages will be understood from the foregoing description, and it will be apparent that various changes may be made thereto without deparconducting materialg from the spirit and scope of the disclosure or sacrificing all of its material advantages, the examples hereinbefore described merely being preferred or exemplary embodiments.

What is claimed is:

1. A circuit board structure, comprising:
a circuit board defining at least one group of pin holes arranged along a predetermined line; and
at least one adsorption strip set on the circuit board and located adjacent to the pin holes;
wherein the adsorption strip extends along a direction substantially parallel to the predetermined line, and a first distance between a side of the adsorption strip adjacent to the corresponding group of pin holes and the predetermined line is less than a second distance between two centers of adjacent pin holes.

2. The circuit board structure of claim 1, wherein there are different adsorption strips set on the circuit board corresponding to different groups of the pin holes are arranged along the predetermined lines in different directions.

3. The circuit board structure of claim 1, wherein there are two groups of pin holes correspondingly are arranged along two parallel predetermined lines.

4. The circuit board structure of claim 3, wherein there are two adsorption strips correspondingly set at two opposite outer sides of two groups of the pin holes are arranged along two parallel predetermined lines.

5. The circuit board structure of claim 1, wherein the adsorption strip is made of metal.

6. The circuit board structure of claim 5, wherein the adsorption strip is a copper strip.

7. The circuit board structure of claim 1, wherein the adsorption strip is isolated from a circuit on the circuit board.

8. The circuit board structure of claim 1, wherein the predetermined line is a straight line.
